(19) United States
(12) Patent Application Publication
(10) Pub. No.: US 2004/0155358 A1
(43) Pub. Date: Aug. 12, 2004

(54) First and second level packaging assemblies and method of assembling package

(76) Inventor: Toshitsune Iijima, Tokyo (JP)

Correspondence Address: Finnegan, Henderson, Farabow, Garrett & Dunner, L.L.P., 1300 I Street, N.W., Washington, DC, 20005-3315, US

(21) Appl. No.: 10/635,538

(22) Filed: Aug. 7, 2003

(30) Foreign Application Priority Data
Feb. 7, 2003 (JP) P2003-030767

(51) Int. Cl. H01L 23/488

(52) U.S. Cl. 257/778; 257/772; 438/108; 438/612

(57) ABSTRACT

A first level packaging assembly includes a chip-mounting base defined by a first surface and a second surface opposite to the first surface; a plurality of external connection lands disposed on the first surface; a plurality of solder balls connected to the external connection lands; a plurality of internal connection lands disposed on the second surface; a plurality of solder joints connected to the internal connection lands including solder materials having lower melting temperature than the solder balls; a semiconductor chip defined by a third surface and a fourth surface opposite to the third surface, connected to the solder joints on the third surface; and an underfill resin sandwiched between the second and third surfaces so as to mold the solder joints.

### CROSS REFERENCE TO RELATED APPLICATIONS

This application is based upon and claims the benefit of priority from the prior Japanese Patent Applications No. P2003-030767, filed on Feb. 7, 2003; the entire contents of which are incorporated herein by reference.

### BACKGROUND OF THE INVENTION

1. Field of the Invention

The present invention relates to semiconductor device technology, more specifically to first and second level packaging assemblies and a method of assembling package using soldering technology.

2. Description of the Related Art

Semiconductor integrated circuits such as LSI have achieved higher levels of integration in recent years. Semiconductor devices themselves are shrinking in geometry size, growing in the degree of on-chip integration, and their pin-counts are increasing. In view of assembling technology for a semiconductor device, a surface-mount package (SMP) has been commonly employed in addition to a conventional lead-insertion type package. As for the SMP, for example, a ball grid array (BGA) and a chip scale or chip size packaging (CSP) are known.

In the SMP, solder bumps made of solder paste are often used as joint balls. For example, a solder paste composed of 62% tin (Sn) and 38% lead (Pb), which is called a “eutectic solder”, is commonly used. However, recently, it has been pointed out that the outflow of lead from electronic products dumped onto reclaimed land pollutes rivers and underground water. Thus, throughout the world, manufacturers are changing the Sn—Pb eutectic, used for mounting printed circuit boards, to lead-free solder alloys.

Typical material examples of lead-free solder alloys, responding to an environmental problem, are tin-silver (Sn—Ag) solder and tin-zinc (Sn—Zn) solder. However, for lead-free solder alloys such as Sn—Ag solder, the melting point is generally higher than that of the conventional eutectic alloy. For example, in the case of a eutectic solder, electrodes can be reflowed at a relatively low temperature of approximately 183 ?C. However, in cases where a lead-free solder is used, reflow has to occur at high temperature conditions of approximately 220 ?C. When reflow is performed at high temperature conditions, strong thermal stresses are applied to semiconductor chips and mounting bases. Therefore, a high thermal resistance is required for semiconductor chips, mounting bases, circuit boards, and the like.

Meanwhile, since recent microprocessors process huge quantities of information at high speed, there have been problems with the resistance of wires interconnecting transistors, and the capacitance of insulators between interconnect wires. For example, wire materials are changing from aluminum (Al) to copper (Cu) having a high electrical conductivity, and insulators are changing from silicon oxide films to materials having low dielectric constants. However, such materials used in recent electronic devices are generally weak in mechanical strength. In particular, low-k films used as insulators within semiconductor chips are significantly weak in mechanical strengths and adhesion intensity because of their porous structures to ensure low dielectric constants. Therefore, when electrodes are ref lowed using a lead-free solder at a high melting point, strong thermal stresses also occur in the low dielectric constant films (low-k films) within the semiconductor chip. Furthermore, the low-k films just under the solder electrodes are damaged by the heat, and the adhesive strength between the semiconductor chip and the mounting base is also decreased.

### SUMMARY OF THE INVENTION

An aspect of the present invention inheres in a first level packaging assembly encompassing a chip-mounting base defined by a first surface and a second surface opposite to the first surface; a plurality of external connection lands disposed on the first surface; a plurality of solder balls connected to the external connection lands; a plurality of internal connection lands disposed on the second surface; a plurality of solder joints connected to the internal connection lands including solder materials having lower melting temperature than the solder balls; a semiconductor chip defined by a third surface and a fourth surface opposite to the third surface, connected to the solder joints on the third surface; and an underfill resin sandwiched between the second and third surfaces so as to mold the solder joints.

Another aspect of the present invention inheres in a second level packaging assembly encompassing a chip-mounting base defined by a first surface and a second surface opposite to the first surface; a plurality of external connection lands disposed on the first surface; a plurality of solder balls connected to the external connection lands; a plurality of internal connection lands disposed on the second surface; a plurality of solder joints connected to the internal connection lands including solder materials having lower melting temperatures than the solder balls; a semiconductor chip defined by a third surface and a fourth surface opposite to the third surface, connected to the solder joints on the third surface; an underfill resin sandwiched between the second and third surfaces so as to mold the solder joints; and a board having a plurality of mounting pads, connected with the solder balls.

Still another aspect of the present invention inheres in a method of assembling a first level packaging assembly embracing connecting a plurality of internal connection lands disposed on a second surface of a chip-mounting base defined by a first surface and the second surface opposite to the first surface with a plurality of chip-side internal connection lands disposed on a third surface of a semiconductor chip defined by the third surface and the fourth surface opposite to the third surface, by a plurality of solder joints between the internal connection lands and the chip-side internal connection lands; injecting an underfill resin between the second and the third surfaces so as to mold the solder joints; and disposing a plurality of solder balls having higher melting temperatures than the solder joints on the external connection lands disposed on the first surface.

### BRIEF DESCRIPTION OF DRAWINGS

FIG. 1 is a sectional view showing an example of first level assembly according to a first embodiment of the present invention.

FIG. 2 is a table showing an example of solder materials employed in The first level packaging assembly shown in FIG. 1.

FIGS. 3A, 3B, and 4A to 4D are sectional views showing an example of assembling The first level packaging assembly according to the first embodiment of the present invention.

FIG. 5 is a sectional view showing an example of first level assembly according to a second embodiment of the present invention.

FIGS. 6A, 6B, and 7A to 7D are sectional views showing an example of assembling The first level packaging assembly according to the second embodiment of the present invention.

FIG. 8 is a sectional view showing an example of first level assembly according to a third embodiment of the present invention.

FIGS. 9A to 9C are sectional views showing an example of assembling The first level packaging assembly according to the third embodiment of the present invention.

FIG. 10 is a sectional view showing a modification of the first level assembly according to a third embodiment of the present invention shown in FIG. 8

FIG. 11 is a sectional view showing an example of second level packaging assembly according to a fourth embodiment of the present invention.

FIGS. 12A to 12C are sectional views showing an example of assembling the second level packaging assembly according to the fourth embodiment of the present invention.

### DETAILED DESCRIPTION OF THE INVENTION

Various embodiments of the present invention will be described with reference to the accompanying drawings. It is to be noted that the same or similar reference numerals are applied to the same or similar parts and elements throughout the drawings, and the description of the same or similar parts and elements will be omitted or simplified. Generally, and as is conventional in the representation of semiconductor devices, it will be appreciated that the various drawings are not drawn to scale from one figure to another nor inside a given figure, and in particular that the layer thicknesses are arbitrarily drawn for facilitating the reading of the drawings. In the following descriptions, numerous details are set forth such as specific signal values, etc. to provide a thorough understanding of the present invention. However, it will be obvious to those skilled in the art that the present invention may be practiced without such specific details.

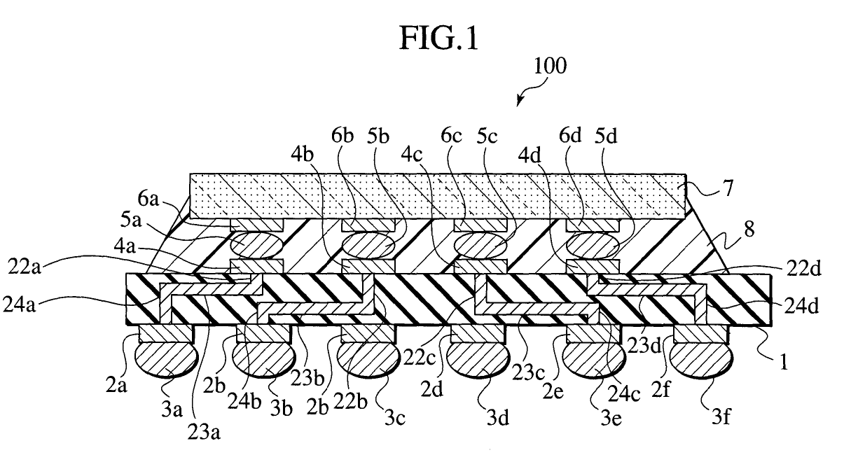

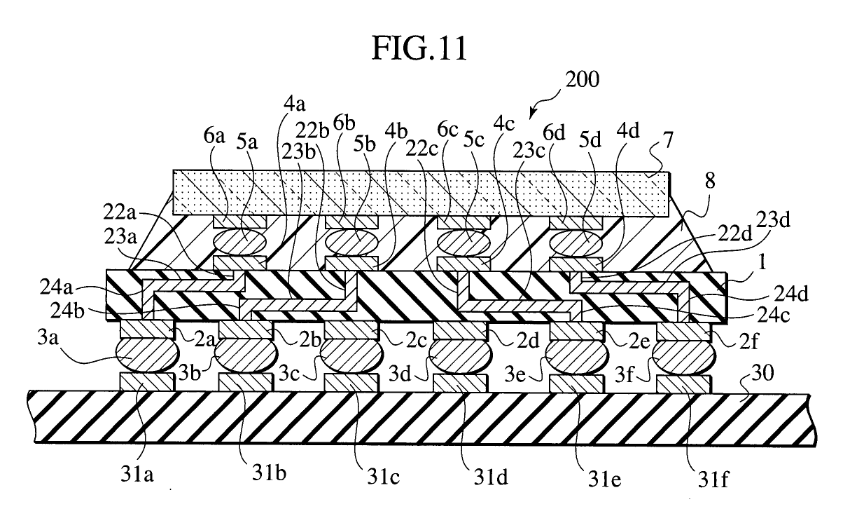

The assembly of levels of electronic devices is classified into several packaging levels in a hierarchy. A first level packaging assembly in the hierarchy indicates an assembly in which a semiconductor chip is mounted on a mounting base and the like. For example, FIGS. 1 to 9C show the first level assemblies 100, 101, 102 and 103. A second level packaging assembly in the hierarchy indicates an assembly in which The first level packaging assembly is mounted on a board. The second level packaging assembly in the hierarchy includes a second level packaging assembly 200 as shown in FIG. 11. A third level assembly indicates an assembly in which the second level packaging assembly is mounted on a motherboard or the like.

### FIRST EMBODIMENT

The first level packaging assembly 100 according to a first embodiment of the present invention encompasses, as shown in FIG. 1: a chip-mounting base 1 defined by a first surface and a second surface opposite to the first surface; a plurality of solder balls 3a, 3b, 3c, 3d, 3e, and 3f connected to the first surface; a plurality of solder joints 5a, 5b, 5c, and 5d connected to the second surface including solder materials having a lower melting temperature than the solder balls; a semiconductor chip 7 defined by a third surface and a fourth surface opposite to the third surface, being connected to the solder joints 5a, 5b, 5c, and 5d on the second surface; and an underfill resin 8 sandwiched between the second and third surfaces so as to surround and encapsulate the solder joints.

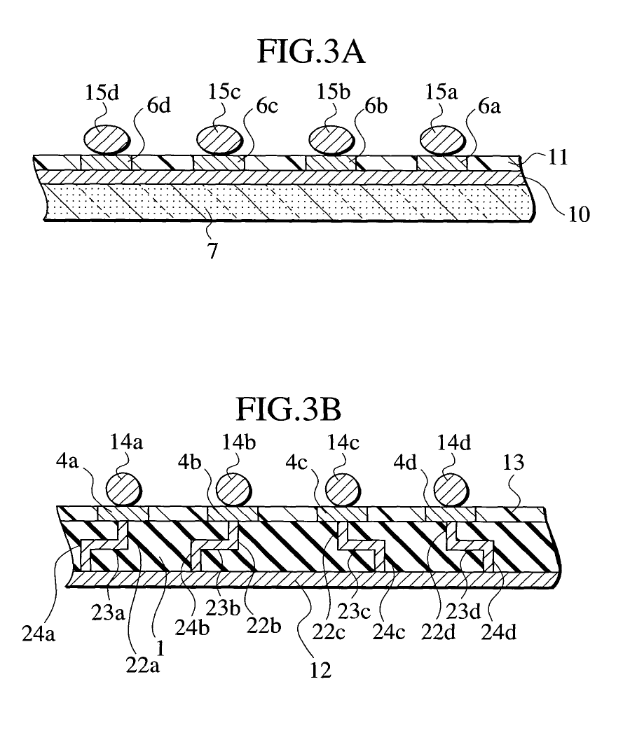

On the third surface of the semiconductor chip 7, circuit elements 10 as shown in FIG. 3A are formed. In FIG. 1, the circuit elements (conductive layer) 10 and a protective film (passivation layer) 11 are omitted. As the circuit elements 10, for example, a plurality of heavily-doped impurity regions doped with donors or acceptors of approximately 1×10¹⁸ cm⁻³ to ×10²¹ cm⁻³ (such as source regions/drain regions or emitter regions/collector regions) or the like are formed. Metal wires made of aluminum (Al), aluminum alloy (Al—Si or Al—Cu—Si) or the like are formed into a multi-layered structure using low dielectric constant films as interlayer dielectrics so as to be connected to the heavily-doped impurity regions. In the uppermost conductive layer, chip-side internal connection lands 6a, 6b, 6c, and 6d are formed. A protective film 11 (not shown) made from an oxide film (SiO₂), a PSG film, a BPSG film, a nitride film (Si₃N₄), a polyimide film or the like is formed on the chip-side internal connection lands 6a, 6b, 6c and 6d. Moreover, the protective film 11 is partially provided with a plurality of openings (window portions) such that the plurality of portions of the electrode layer are exposed, and then the chip-side internal connection lands 6a, 6b, 6c, and 6d are formed.

As shown in FIG. 1, a plurality of external connection lands 2a, 2b, 2c, 2d, 2e, and 2f are aligned at equal intervals on the first surface of the chip-mounting base 1. The positions, material, number, and the like of the external connection lands 2a, 2b, 2c, 2d, 2e, and 2f are not limited. For example, the external connection lands 2a, 2b, 2c, 2d, 2e, and 2f may be aligned in a matrix form on the entire first surface of the chip-mounting base 1. The external connection lands 2a, 2b, 2c, 2d, 2e, and 2f may be aligned along the four sides of the quadrangle which define the outline of the chip-mounting base 1, and do not need to be aligned in the vicinity of the center of the chip-mounting base 1.

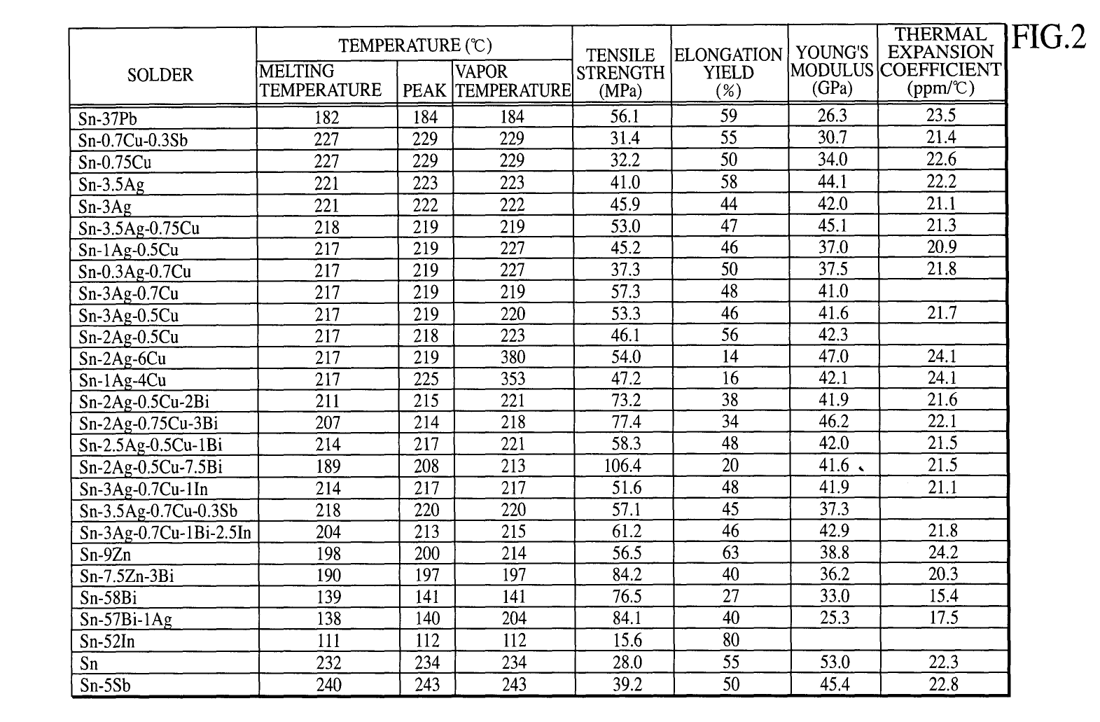

For the solder balls 3a, 3b, 3c, 3d, 3e, and 3f respectively connected to the external connection lands 2a, 2b, 2c, 2d, 2e, and 2f, a lead-free solder material is used. As the lead-free solder material, a Tin-Copper (Sn—Cu) alloy, Tin-Silver (Sn—Ag) alloy, Tin-Silver-Copper (Sn—Ag—Cu) alloy, Tin (Sn), Tin-5 Antimony (Sn—5Sb) alloy, and the like shown in FIG. 2 can be used. The melting temperatures of these lead-free solder materials shown in FIG. 2 are approximately 208 ?C. to 243 ?C. and higher than the melting temperature of the Sn—Pb alloy (containing lead) which ranges from 182 ?C. to 184 ?C. The tensile strengths of the lead-free solder materials, except for some Sn—Ag—Cu alloys, are as low as 31.4 to 53.3 MPa, compared to 56.0 MPa of the Sn—Pb alloy. The elongation of all the lead-free solder materials is as low as 16 to 56%, compared to 59% of the Sn—Pb alloy. The Young's moduli of the lead-free solder materials are as large as 30.7 to 47.0 GPa, compared to 26.3 GPa for the Sn—Pb alloy.

On the second surface of the chip-mounting base 1 shown in FIG. 1, a plurality of internal connection lands 4a, 4b, 4c, and 4d are aligned at equal intervals. The positions and number of the internal connection lands 4a, 4b, 4c, and 4d are not limited. The solder joints 5a, 5b, 5c, and 5d are connected to these internal connection lands 4a, 4b, 4c, and 4d, respectively. The solder joints 5a, 5b, 5c, and 5d contain a solder material having a lower melting temperature than the solder balls 3a, 3b, 3c, 3d, 3e, and 3f. Note that a lead-free solder is used for the solder joints 5a, 5b, 5c, and 5d. As the lead-free solder, for example, the lead-free solder materials including a Tin-Zinc (Sn—Zn) alloy, Tin-Bismuth (Sn—Bi) alloy, Tin-Indium (Sn—In) alloy, and Tin-Bismuth-Silver (Sn—Bi—Ag) alloy shown in FIG. 2 can be used. The peak melting temperatures of these lead-free solder materials range from approximately 112° C. to 197° C. The lead-free solder materials have melting temperatures equal to or lower than that of the Sn—Pb alloy. Note that, as shown in FIG. 2, the tensile strengths of the Sn—Zn, Sn—Bi, and Sn—Bi—Ag alloys range from 56.5 to 84.2 MPa, which are larger than the 56 MPa of the Sn—Pb alloy. The elongation yields of the Sn—Zn and Sn—In alloys are 63% and 80%, respectively, and larger than 59% of the Sn—Pb alloy. The values of Young's moduli of the lead-free solders are approximately equivalent to the 26.3 GPa of the Sn—Pb alloy.

In the chip-mounting base 1 shown in FIG. 1, the following components are disposed: a plurality of upper via plugs 22a, 22b, 22c, and 22d; a plurality of inner buried wires 23a, 23b, 23c, and 23d connected to the upper via plugs 22a, 22b, 22c, and 22d respectively; and a plurality of lower via plugs 24a, 24b, 24c, and 24d respectively connected to the inner buried wires 23a, 23b, 23c, and 23d. The upper via plugs 22a, 22b, 22c, and 22d are respectively connected to the internal connection lands 4a, 4b, 4c, and 4d. The lower via plugs 24a, 24b, 24c, and 24d are respectively connected to the external connection lands 2a, 2b, 2e, and 2f.

As the material of the chip-mounting base 1, various organic synthetic resins and inorganic materials including ceramic and glass can be used. Among organic synthetic resins, phenolic resin, polyester resin, epoxy resin, polyimide resin, fluoroplastic, and the like-can be used. Meanwhile, paper, woven glass fabric, a glass backing material, or the like is used as a backing material that becomes a core in forming a platy structure. As a general inorganic base material, ceramic can be used. Alternatively, a metal substrate is used in order to improve the heat-radiating characteristics. In the case where a transparent substrate is needed, glass is used. As the raw material of a ceramic substrate, alumina (Al₂O₃), mullite (3Al₂O₃.2SiO₂), beryllia (BeO), aluminum nitride (AlN), silicon nitride (SiN), and the like can be used. Furthermore, it is possible to use a metal-base substrate (metal insulator substrate) in which a polyimide resin plate having high thermal resistance is laminated onto metal, such as iron or copper, to form a multi-layered structure. The thickness of the chip-mounting base 1 is not limited.

As for the external connection lands 2a, 2b, 2c, 2d, 2e, and 2f, the internal connection lands 4a, 4b, 4c, and 4d, and the chip-side internal connection lands 6a, 6b, 6c, and 6d, electrically conductive material such as Al, Al—Si, Al—Cu—Si, gold, copper, or the like can be used. Alternatively, other electrodes can be provided through a plurality of signal lines such as gate wires connected to a plurality of polysilicon gate electrodes. Instead of gate electrodes made from polysilicon, it is possible to use gate electrodes made from a metal having a higher melting temperature including tungsten (W), titanium (Ti), and molybdenum (Mo), silicides thereof (WSi₂, TiSi₂ and MoSi₂), polycide using these silicides, or the like. As the underfill resin 8, organic synthetic resins including epoxy resin can be used.

In the first assembly 100 according to the first embodiment of the present invention, a lead-free solder material such as Sn—Zn alloy is used for the solder joints 5a, 5b, 5c, and 5d arranged between the semiconductor chip 7 and the chip-mounting base 1. Solder materials such as Sn—Zn and the like have peak melting temperatures of 197 ?C. to 214 ?C., which are of the order of those of lead-containing solder materials. Therefore, the thermal stresses, during reflow, of the semiconductor chip 7 and the chip-mounting base 1 can be suppressed to the same level as in a case where lead-containing solder materials are used. Moreover, lead-free solder materials having lower melting temperature including the Sn—In alloy as shown in FIG. 2 melt at approximately 112 ?C. to 197 ?C. Therefore, strong thermal stresses are not applied to the low dielectric constant films disposed in the semiconductor chip 7, particularly to the low dielectric constant insulator film disposed on the chip-side internal connection lands 6a, 6b, 6c, and 6d, compared with the case when Sn—Ag alloys are used. Furthermore, since strong thermal stress is not added to the solder joints 5a, 5b, 5c, and 5d, the internal connection lands 4a, 4b, 4c, and 4d and the chip-side internal connection lands 6a, 6b, 6c, and 6d will not break. Moreover, for the solder balls 3a, 3b, 3c, 3d, 3e, and 3f of the first assembly 100 shown in FIG. 1, a lead-free material having a higher melting temperature than the solder joints 5a, 5b, 5c, and 5d is used. Therefore, when the solder balls 3a, 3b, 3c, 3d, 3e, and 3f are mounted on the first surface of the chip-mounting base 1 to be reflowed, the solder joints 5a, 5b, 5c, and 5d also melt due to the generated heat. The thermal stresses applied to the low dielectric constant films disposed on the circuit element surface of the semiconductor chip 7 or to the wires arranged in the chip-mounting base 1 are absorbed by the solder joints 5a, 5b, 5c, and 5d. Accordingly, breakage of the semiconductor chip 7 and the chip-mounting base 1 can be prevented.

Next, an assembly method of the first assembly 100 according to the first embodiment of the present invention is described. Here, it is obvious that the assembly method of the first assembly 100 described below is one example and the assembly of the first assembly 100 is feasible by other various assembly methods including modifications of the present embodiment.

(a) First, as shown in FIG. 3A, a plurality of heavily-doped impurity regions (source regions/drain regions or emitter regions/collector regions, etc.) or the like doped with donors or acceptors of, for example, approximately 1×10¹⁸ cm⁻³ to 1×10²¹ cm⁻³ are formed on the third surface of the semiconductor chip 7. Then, metal wires made from Al, Al—Si, Al—Cu—Si, or the like are formed into a multi-layered structure using low dielectric constant films as interlayer dielectrics so as to be connected to the heavily-doped impurity regions. In the uppermost conductive layer, the chip-side internal connection lands 6a, 6b, 6c, and 6d are formed. Next, a protective film 11 made from a SiO₂ film, a PSG film, a BPSG film, a Si₃N₄ film, a polyimide film, or the like is formed on the chip-side internal connection lands 6a, 6b, 6c, and 6d. Subsequently, the protection film 11 is partially provided with a plurality of openings such that the plurality of portions of the electrode layer are exposed, thus forming the chip-side internal connection lands 6a, 6b, 6c, and 6d. The chip-side internal connection lands 6a, 6b, 6c, and 6d do not need to be aligned at the peripheral portion of the semiconductor element (semiconductor chip). Next, lower melting temperature solder balls 15a, 15b, 15c, and 15d are formed on the chip-side internal connection lands 6a, 6b, 6c, and 6d by use of solder plating, solder paste printing, solder ball mounting, or the like. As the solder material, an alloy having a melting point equivalent to or lower than that of the Sn—Pb eutectic solder is used. For example, Sn—Bi or Sn—In solder materials can be used. It is possible to apply flux (not shown) to the chip-side solder balls 15a, 15b, 15c, and 15d.

(b) Next, as shown in FIG. 3B, a chip-mounting base 1 having internal connection lands 4a, 4b, 4c, and 4d on the second surface thereof is prepared. A protective film (solder resist) 13 is patterned on the second surface of the chip-mounting base 1. Then, lower melting temperature solder balls 14a, 14b, 14c, and 14d are formed on the internal connection lands 4a, 4b, 4c, and 4d. For the lower melting temperature solder balls 14a, 14b, 14c, and 14d, a solder material similar to that of the lower melting temperature solder balls 15a, 15b, 15c, and 15d described in FIG. 3A is used. It is possible to apply flux (not shown) to the lower melting temperature solder balls 14a, 14b, 14c, and 14d.

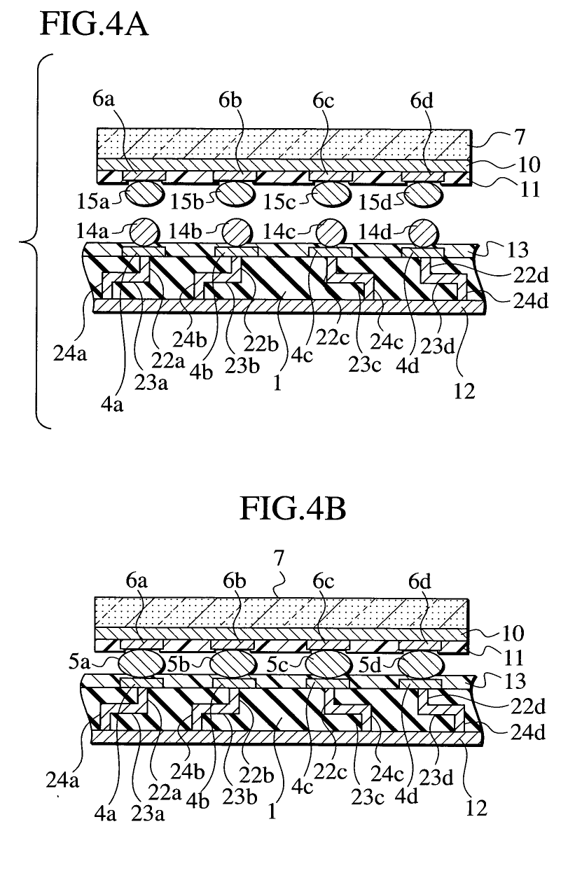

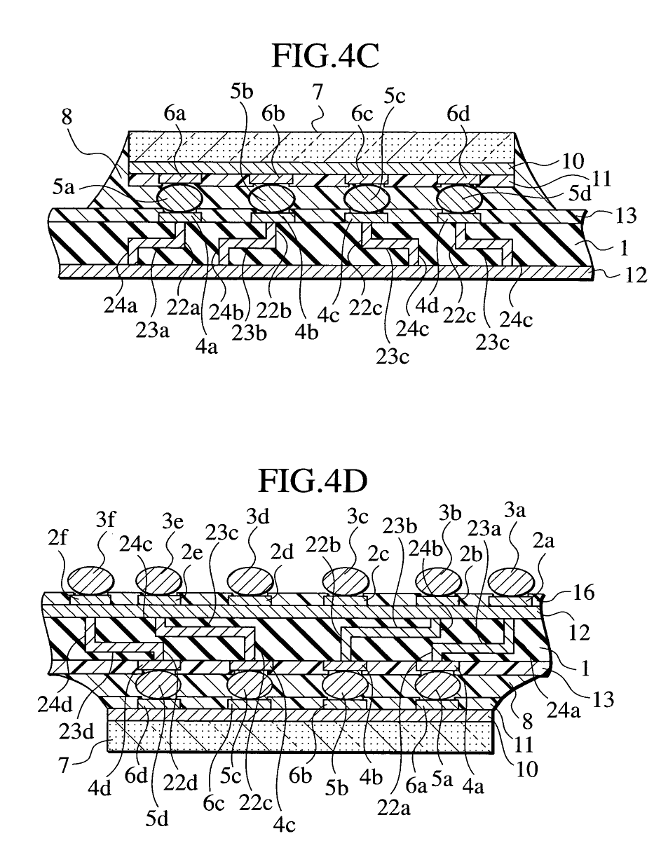

(c) Next, as shown in FIG. 4A, the lower melting temperature solder balls 15a, 15b, 15c, and 15d and the lower melting temperature solder balls 14a, 14b, 14c, and 14d are opposed to each other. Then, as shown in FIG. 4B, the lower melting temperature solder balls 15a, 15b, 15c, and 15d and the lower melting temperature solder balls 14a, 14b, 14c, and 14d are melted so as to be adhered together by reflowing. The lower melting temperature solder balls 15a, 15b, 15c, and 15d and the lower melting temperature solder balls 14a, 14b, 14c, and 14d are respectively adhered to each other, whereby the solder joints 5a, 5b, 5c, and 5d are formed. Note that the lower melting temperature solder balls 15a, 15b, 15c, and 15d may be directly adhered to the internal connection lands 4a, 4b, 4c, and 4d, without aligning the lower melting temperature solder balls 14a, 14b, 14c, and 14d of the chip.

(d) Next, as shown in FIG. 4C, the underfill resin 8 is injected between the third surface of the semiconductor chip 7 and the second surface of the chip-mounting base 1 which are connected by the solder joints 5a, 5b, 5c, and 5d, thus sealing the region between the semiconductor chip 7 and the chip-mounting base 1. Subsequently, as shown in FIG. 4D, the external connection lands 2a, 2b, 2c, 2d, 2e, and 2f and a protective film 16 are formed on a mounting-base-side conductive layer 12. Then, the solder balls 3a, 3b, 3c, 3d, 3e, and 3f are formed on the external connection lands 2a, 2b, 2c, 2d, 2e, and 2f. For example, a solder material having higher melting temperature such as Sn—Cu, Sn—Ag, or Sn—Ag—Cu alloys shown in FIG. 2, is mounted as the solder balls 3a, 3b, 3c, 3d, 3e, and 3f by solder plating, solder ball mounting, solder paste printing, or the like.

As described above, the first assembly 100 as shown in FIG. 1 can be manufactured. According to the first assembly 100 of the first embodiment of the present invention, since lead-free solder materials are used for the solder joints 5a, 5b, 5c, and 5d and the solder balls 3a, 3b, 3c, 3d, 3e, and 3f, it is possible to prevent lead, as previously used in semiconductors, from entering out to the environment. Since the solder joints 5a, 5b, 5c, and 5d are made from a material having a melting temperature nearly equal to the lead eutectic solder, the thermal stresses generated by reflowing can be minimized. Therefore, it is possible to prevent damage to the low dielectric constant films formed in the circuit elements 10 of the semiconductor chip 7 or the wires disposed on the chip-mounting base 1. Moreover, the melting temperature of the solder material used for the solder balls 3a, 3b, 3c, 3d, 3e, and 3f is higher than that of the solder joints 5a, 5b, 5c, and 5d. Therefore, when the solder balls 3a, 3b, 3c, 3d, 3e, and 3f are mounted on the first surface of the chip-mounting base 1 and reflowed, the solder joints 5a, 5b, 5c, and 5d also melt due to the heat. Accordingly, the thermal stresses applied to the wires disposed in the semiconductor chip 7 or the chip-mounting base 1 can be suppressed to the same level as that of lead-containing eutectic solders. Moreover, it is possible to prevent the breakage of materials, which have weak mechanical strength, formed in the circuit elements 10 of the semiconductor chip 7, particularly, the breakage of the low dielectric constant films and the like disposed directly on the solder joints 5a, 5b, 5c, and 5d.

### SECOND EMBODIMENT

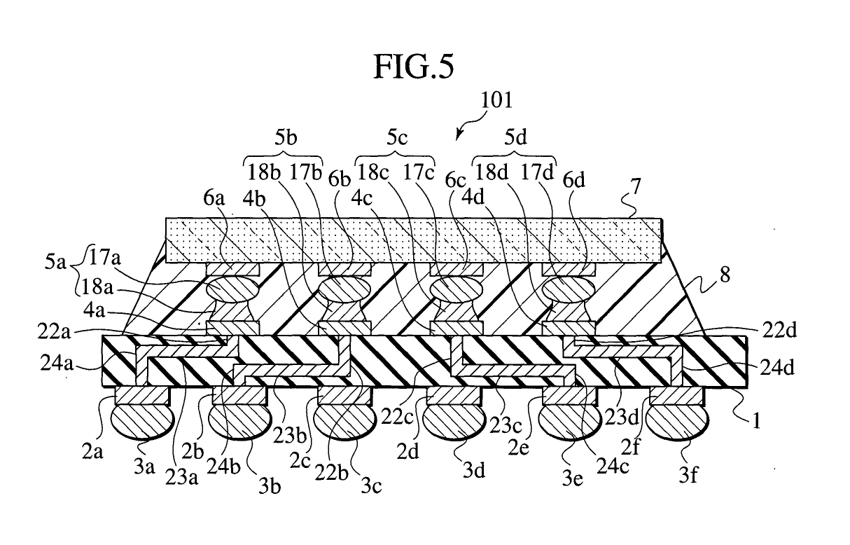

As shown in FIG. 5, a first assembly 101 according to a second embodiment of the present invention is different from the first assembly 100 shown in FIG. 1 in that solder joints 5a, 5b, 5c, and 5d disposed between a second surface of a chip-mounting base 1 and a third surface of a semiconductor chip 7 have lower melting temperature solder bumps (a first group) 18a, 18b, 18c, and 18d and higher melting temperature solder balls (a second group) 17a, 17b, 17c, and 17d. The lower melting temperature solder bumps 18a, 18b, 18c, and 18d have a lower melting temperature than Tin-Lead solder alloys. The higher melting temperature solder balls 17a, 17b, 17c, and 17d have a higher melting temperature than the lower melting temperature solder bumps 18a, 18b, 18c, and 18d.

The lower melting temperature solder bumps 18a, 18b, 18c, and 18d may have spherical shapes practically similar to those of the higher melting temperature solder balls 17a, 17b, 17c, and 17d. Moreover, the higher melting temperature solder balls 17a, 17b, 17c, and 17d may have protruding shapes similar to those of the lower melting temperature solder bumps 18a, 18b, 18c, and 18d, other than spherical shapes. The rest of the structure of the first assembly 101 is similar to that of the first assembly 100 shown in FIG. 1, and hence, duplicate description is omitted.

As shown in FIG. 5, the lower melting temperature solder bumps 18a, 18b, 18c, and 18d are respectively connected to internal connection lands 4a, 4b, 4c, and 4d. The higher melting temperature solder balls 17a, 17b, 17c, and 17d are respectively connected to the lower melting temperature solder bumps 18a, 18b, 18c, and 18d. The higher melting temperature solder balls 17a, 17b, 17c, and 17d are respectively connected to chip-side internal connection lands 6a, 6b, 6c, and 6d. For the higher melting temperature solder balls 17a, 17b, 17c, and 17d, a solder material having a higher melting point than the lower melting temperature solder bumps 18a, 18b, 18c, and 18d is used. For example, in the case where a solder alloy of Sn—Bi alloy, Sn—In alloy, Sn—Bi—Zn alloy or the like shown in FIG. 2 is used for the lower melting temperature solder bumps 18a, 18b, 18c, and 18d, it is possible to use Sn—Cu, Sn—Ag, Sn—Ag—Cu, or Sn—Pb alloys and the like, shown in FIG. 2, for the higher melting temperature solder balls 17a, 17b, 17c, and 17d. Note that the higher melting temperature solder balls 17a, 17b, 17c, and 17d may be connected to the internal connection lands 4a, 4b, 4c, and 4d, and the lower melting temperature solder bumps 18a, 18b, 18c, and 18d may be connected to the chip-side internal connection lands 6a, 6b, 6c, and 6d.

Next, an assembly method of the first assembly 101 according to the second embodiment of the present invention is described. Here, it is obvious that the assembly method of the first assembly 101 described below is one example and the assembly of the first assembly 101 is feasible by other various assembly methods including modifications of the present embodiment.

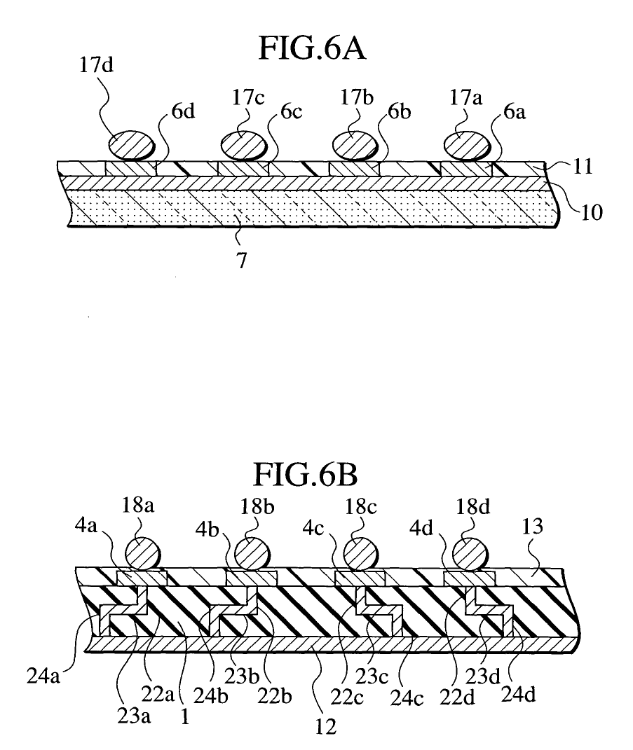

(a) First, as shown in FIG. 6A, the protective film 11 is formed on the circuit elements 10 disposed on the third surface of the semiconductor chip 7. Then, the chip-side internal connection lands 6a, 6b, 6c, and 6d are formed on the protective film 11. Next, higher melting temperature solder balls 17a, 17b, 17c, and 17d are formed on the chip-side internal connection lands 6a, 6b, 6c, and 6d by use of solder plating, solder paste printing, solder ball mounting, or the like. As the solder material, an alloy having a higher melting temperature than the Sn—Pb eutectic solder is used. For example, a lead-free solder such as Sn—Cu, Sn—Ag, Sn—Ag—Cu, Cu—Sb alloys can be used. It is possible to apply flux (not shown) to the higher melting temperature solder balls 17a, 17b, 17c, and 17d.

(b) Next, as shown in FIG. 6B, a chip-mounting base 1 having internal connection lands 4a, 4b, 4c, and 4d on the second surface thereof is prepared. A protective film 13 is patterned on the second surface of the chip-mounting base 1. Then, lower melting temperature solder bumps 18a, 18b, 18c, and 18d are formed on the internal connection lands 4a, 4b, 4c, and 4d. For the lower melting temperature solder bumps 18a, 18b, 18c, and 18d, a solder material having a lower melting point than the higher melting temperature solder balls 17a, 17b, 17c, and 17d can be used. For example, when Sn—Ag alloys are used as the higher melting temperature solder balls 17a, 17b, 17c, and 17d, Sn—Bi alloys, Sn—Bi—Ag alloys can be used as the lower melting temperature solder bumps 18a, 18b, 18c, and 18d. It is possible to apply flux (not shown) to the lower melting temperature solder bumps 18a, 18b, 18c, and 18d.

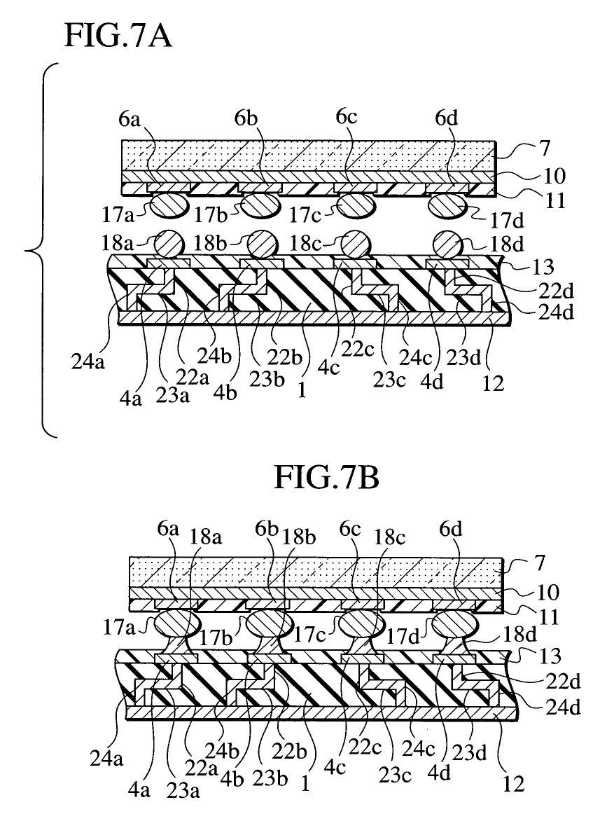

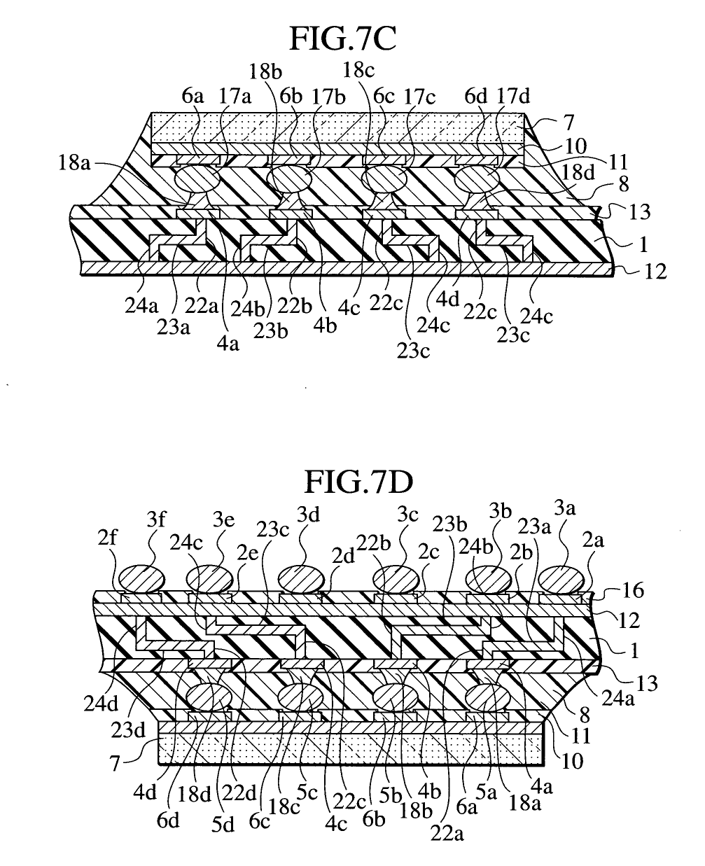

(c) Next, as shown in FIG. 7A, the higher melting temperature solder balls 17a, 17b, 17c, and 17d and the lower melting temperature solder bumps 18a, 18b, 18c, and 18d are opposed to each other. Then, as shown in FIG. 7B, the higher melting temperature solder balls 17a, 17b, 17c, and 17d and the lower melting temperature solder bumps 18a, 18b, 18c, and 18d are melted so as to be adhered together by reflowing. The lower melting temperature solder bumps 18a, 18b, 18c, and 18d melt and adhere to the higher melting temperature solder balls 17a, 17b, 17c, and 17d.

(d) Next, as shown in FIG. 7C, the underfill resin 8 is injected between the third surface of the semiconductor chip 7 and the second surface of the chip-mounting base 1 which are connected by the higher melting temperature solder balls 17a, 17b, 17c, and 17d and the lower melting temperature solder bumps 18a, 18b, 18c, and 18d, thus sealing a region between the semiconductor chip 7 and the chip-mounting base 1. Next, as shown in FIG. 7d, the external connection lands 2a, 2b, 2c, 2d, 2e, and 2f and a protective film 16 are formed on a mounting-base-side conductive layer 12. Then, the solder balls 3a, 3b, 3c, 3d, 3e, and 3f are formed on the external connection lands 2a, 2b, 2c, 2d, 2e, and 2f.

As described above, the first assembly 101 as shown in FIG. 5 can be made. According to the first assembly 101 of the second embodiment of the present invention, the lower melting temperature solder bumps 18a, 18b, 18c, and 18d melt when the solder balls 3a, 3b, 3c, 3d, 3e, and 3f are reflowed. Therefore, thermal stresses occurring between the semiconductor chip 7 and the chip-mounting base 1 can be absorbed by the lower melting temperature solder bumps 18a, 18b, 18c, and 18d. Accordingly, it is possible to prevent the breakage of materials having weak mechanical strength formed in the circuit elements 10 of the semiconductor chip 7, particularly, the breakage of the low dielectric constant films and the like disposed directly on the solder joints 5a, 5b, 5c, and 5d. Furthermore, when other assemblies or parts are mounted on The first level packaging assembly 101 using lead-free solder alloys, thermal stresses between the semiconductor chip 7 and the chip-mounting base 1 can be suppressed to the same level as in a case where lead-containing eutectic solders are used.

### THIRD EMBODIMENT

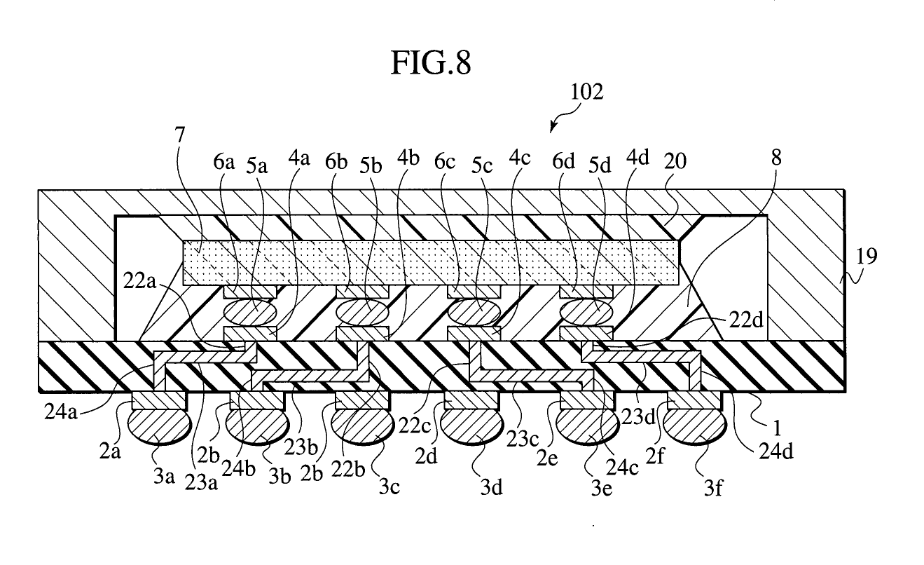

As shown in FIG. 8, a first assembly 102 according to a third embodiment of the present invention is different from the first assembly 100 shown in FIG. 1 in that a heat sink 19 is disposed on the second surface so as to surround the semiconductor chip 7. The heat sink 19 has a box shape having a square hollow space therein. The semiconductor chip 7 is disposed in the hollow space. The underfill resin 20 is disposed between the fourth surface of the semiconductor chip 7 and the hollow space of the heat sink 19. The heat sink 19 can be made from aluminum plate or the like.

Next, an assembly method of the first assembly 102 according to the third embodiment of the present invention is described. Since the method of assembling The first level packaging assembly 102 before attaching the heat sink 19 is the same shown in FIGS. 3A to 4B, a detailed explanation is omitted.

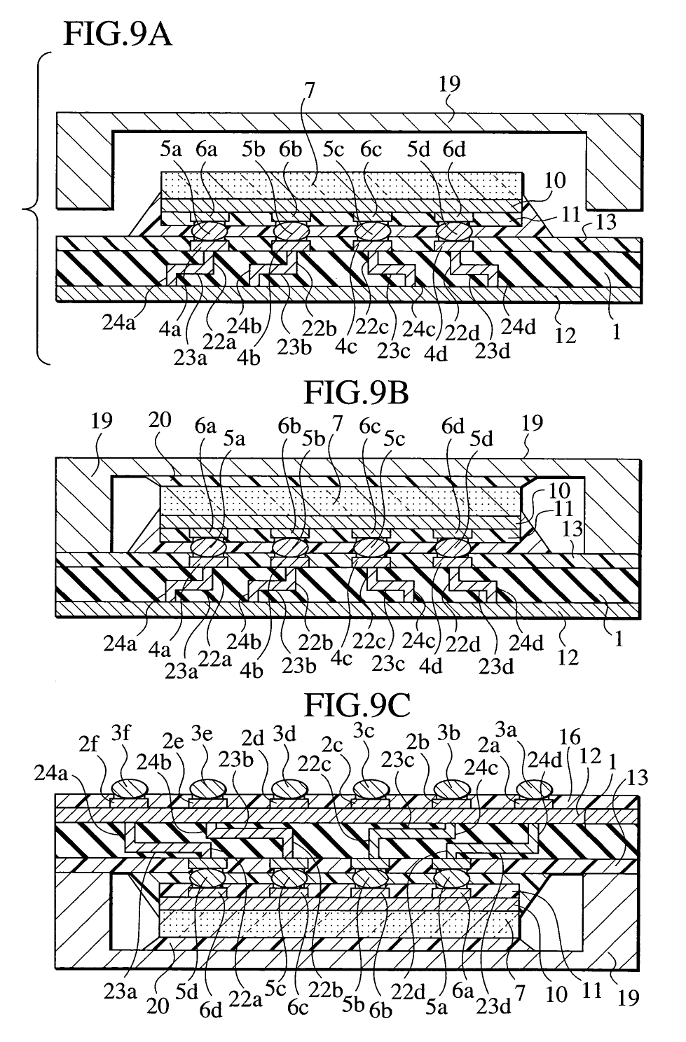

As shown in FIG. 9A, the heat sink 19 and a surface of the semiconductor chip 7 are opposed to each other. Then the underfill resin 20 is injected between the fourth surface of the semiconductor chip 7 and the heat sink 19 and adhered as shown FIG. 9B. The edges of the heat sink 19 connected with the chip-mount base 1 are also adhered by the resin.

Next, as shown in FIG. 9C, the external connection lands 2a, 2b, 2c, 2d, 2e, and 2f and a protective film 16 are formed on a mounting-base-side conductive layer 12. Then, the solder balls 3a, 3b, 3c, 3d, 3e, and 3f are formed on the external connection lands 2a, 2b, 2c, 2d, 2e, and 2f. For example, a solder material having a higher melting temperature than that of eutectic solder, such as Sn—Cu, Sn—Ag, or Sn—Ag—Cu alloys shown in FIG. 2, is mounted as the solder balls 3a, 3b, 3c, 3d, 3e, and 3f by solder plating, solder ball mounting, solder paste printing, or the like

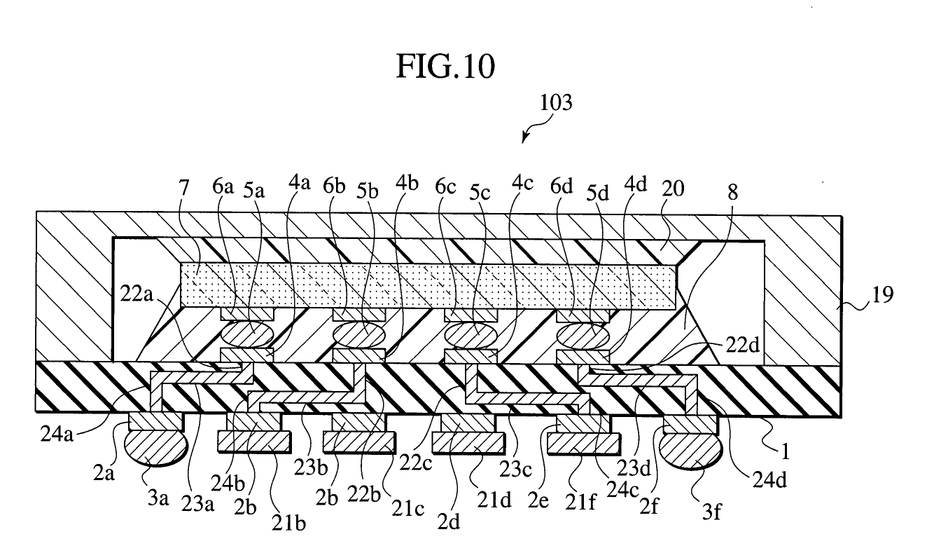

As described above, the first assembly 102 as shown in FIG. 8 can be manufactured. According to the first assembly 102 of the third embodiment of the present invention, heat sink 19 can efficiently emit the heat generated by the semiconductor chip 7. Furthermore, since the solder joints 5a, 5b, 5c, and 5d are made from a material having a melting temperature nearly equal to the lead eutectic solder, the thermal stresses generated by ref lowing can be minimized. Therefore, it is possible to prevent damage of the low dielectric constant films formed in the circuit elements 10 of the semiconductor chip 7 or the wires disposed on the chip-mounting base 1. Moreover, the melting temperature of the solder material used for the solder balls 3a, 3b, 3c, 3d, 3e, and 3f is higher than that of the solder joints 5a, 5b, 5c, and 5d. Therefore, when the solder balls 3a, 3b, 3c, 3d, 3e, and 3f are mounted on the first surface of the chip-mounting base 1 and reflowed, the solder joints 5a, 5b, 5c, and 5d also melt due to the heat. Accordingly, the thermal stresses applied to the wires disposed in the semiconductor chip 7 or the chip-mounting base 1 can be suppressed to the same level as that of lead-containing eutectic solders. Moreover, it is possible to prevent the breakage of materials having weak mechanical strength formed in the circuit elements 10 of the semiconductor chip 7, and particularly, the breakage of the low dielectric constant films and the like disposed directly on the solder joints 5a, 5b, 5c, and 5d. As shown in FIG. 10, chip capacitor 21b, 21c, 21d, and 21f can be disposed on the external connection lands 2a, 2b, 2c, 2d, 2e respectively.

### FOURTH EMBODIMENT

As shown in FIG. 11, a second assembly 200 according to a fourth embodiment of the present invention is different from the first assembly 100 shown in FIG. 1 in that a board 30 having mounting pads 31a, 31b, 31c, 31d, 31e, and 31f is connected with the solder balls 3a, 3b, 3c, 3d, 3e, and 3f respectively.

On the surface of the board 30, the mounting pads 31a, 31b, 31c, 31d, 31e, and 31f are aligned at equal intervals. The positions, material, number, and the like of the mounting pads 31a, 31b, 31c, 31d, 31e, and 31f are not limited to that shown. For the solder balls 3a, 3b, 3c, 3d, 3e, and 3f respectively connected to the mounting pads 31a, 31b, 31c, 31d, 31e, and 31f, a lead-free solder material is used. As the lead-free solder material, Sn—Cu alloy, Sn—Ag alloy, Sn—Ag—Cu alloy, Sn alloy, Sn—5Sb alloy, and the like shown in FIG. 2 can be used. Note that, the melting temperatures of these lead-free solder materials shown in FIG. 2 are between approximately 208° C. and 243° C., and higher than the melting temperature of the Sn—Pb alloy (containing lead) which ranges from 182° C. to 184° C.

For the the solder joints 5a, 5b, 5c, and 5d connected to the internal connection lands 4a, 4b, 4c, and 4d, solder materials having lower melting temperatures than the solder balls 3a, 3b, 3c, 3d, 3e, and 3f are used. For example, lead-free solders such as an Sn—Zn alloy, Sn—Bi alloy, Sn—In alloy, Sn—Bi—Ag alloy can be used. The peak melting temperatures of these lead-free solder materials ranges approximately from 112° C. to 197° C. The lead-free solder materials have melting temperatures equal to or lower than that of the Sn—Pb alloy. Note that, solder materials used as the internal connection lands 4a, 4b, 4c, and 4d can be changed according to the materials used as the solder balls 3a, 3b, 3c, 3d, 3e, and 3f.

Next, an assembly method of the first assembly 200 according to the fourth embodiment of the present invention is described. Since the first assembly mounted on the board 30 is substantially the same as shown in FIG. 1, detailed explanations about assembling method of the first assembly are omitted. Moreover, the upper via plugs 22a, 22b, 22c, and 22d, the inner buried wires 23a, 23b, 23c, and 23d, and the lower via plugs 24a, 24b, 24c, as shown in FIG. 11 are omitted.

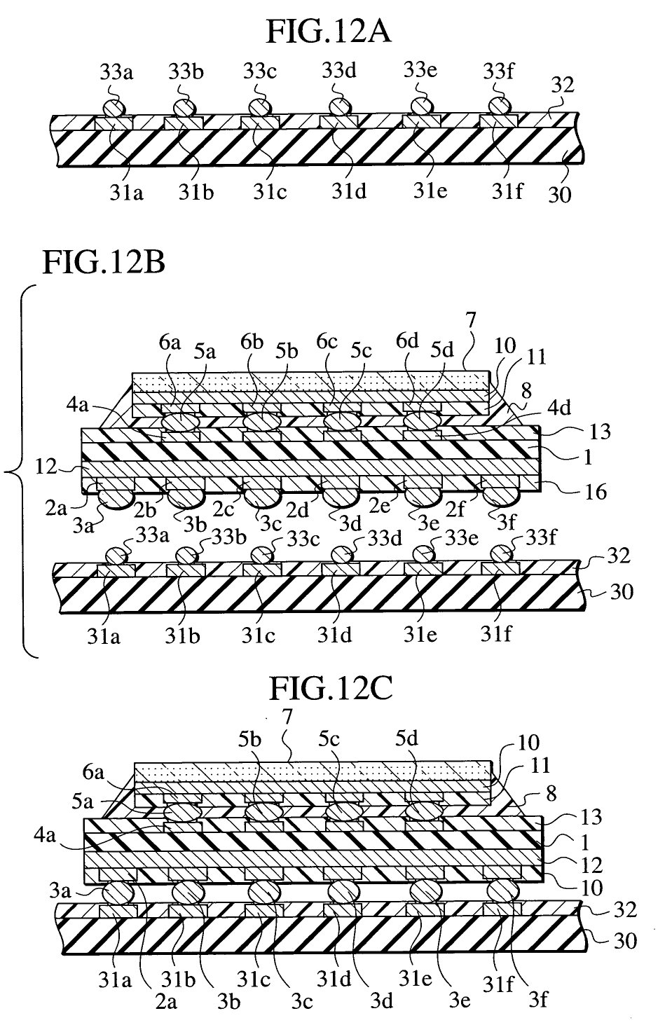

As shown in FIG. 12A, a board 30 having internal connection lands 4a, 4b, 4c, and 4d on the second surface thereof is prepared. A protective film 32 is patterned on the second surface of the board 30 by use of solder plating, solder paste printing, solder ball mounting, or the like. Subsequently, the protection film 32 is partially provided with a plurality of openings such that a plurality of portions of the electrode layer are exposed, thus forming the mounting pads 31a, 31b, 31c, 31d, 31e, and 31f. Next, higher melting temperature solder balls 33a, 33b, 33c, 33d, 33e and 33f are respectively formed on the mounting pads 31a, 31b, 31c, 31d, 31e, and 31f by use of solder plating, solder paste printing, solder ball mounting, or the like. As the solder material, an alloy having a melting point equivalent to or higher than that of the Sn—Pb eutectic solder is used. For example, a lead-free alloy such as Sn—Cu alloy, Sn—Ag alloy, and Sn—Ag—Cu can be used. It is possible to apply flux (not shown) to the mounting pads 31a, 31b, 31c, 31d, 31e, and 31f.

Next, as shown in FIG. 12B, the higher melting temperature solder balls 33a, 33b, 33c, 33d, 33e and 33f and the solder balls 3a, 3b, 3c, 3d, 3e, and 3f are opposed to each other. Then, as shown in FIG. 12C, the higher melting temperature solder balls 33a, 33b, 33c, 33d, 33e and 33f and the solder balls 3a, 3b, 3c, 3d, 3e, and 3f are melted to be adhered together by ref lowing. Note that solder balls 3a, 3b, 3c, 3d, 3e, and 3f may be directly adhered to the mounting pads 31a, 31b, 31c, 31d, 31e, and 31f, without aligning the higher melting temperature solder balls 33a, 33b, 33c, 33d, 33e and 33f of the board 30.

As described above, the second assembly 200 as shown in FIG. 11 can be manufactured. According to the second assembly 200 of the fourth embodiment of the present invention, the solder joints 5a, 5b, 5c, and 5d melt when the solder balls 3a, 3b, 3c, 3d, 3e, and 3f are mounted on the board 30 by reflowing. Therefore, the thermal stresses occurred between the semiconductor chip 7 and the chip-mounting base 1 can be absorbed by the solder joints 5a, 5b, 5c, and 5d. Accordingly, it is possible to prevent the breakage of materials having weak mechanical strength formed in the circuit elements 10 of the semiconductor chip 7, particularly, the breakage of the low dielectric constant films and the like disposed directly on the solder joints 5a, 5b, 5c, and 5d.

### Other Embodiments

Various modifications will become possible for those skilled in the art upon receiving the teachings of the present disclosure without departing from the scope thereof.

As for the first assembly shown in FIG. 1, materials of the solder joints 5a, 5b, 5c, and 5d can be partially changed. When the solder joints 5a, 5b, 5c, and 5d are heated by reflowing, the semiconductor chip 7 and chip-mounting base 1 are elongated. The thermal stresses caused by heat expansion (elongation) occurring at the central parts of the semiconductor chip 7 or the chip-mounting base 1 are weak. However, thermal stresses occurring at the edges of the semiconductor chip 7 and the chip-mounting base 1 are strong. Therefore, lead-free solders having higher melting temperature can be applied to the solder joints 5b and 5c. The lead-free solders having lower melting temperatures can be applied to the solder joints 5a and 5d. Accordingly, it is possible to prevent the breakage of materials that have weak mechanical strengths formed in the circuit elements 10 of the semiconductor chip 7, particularly, the breakage of the low dielectric constant films and the like disposed directly on the solder joints 5a, 5b, 5c, and 5d.

As for The first level packaging assembly 101 shown in FIG. 5, Cu bumps, Ag bumps, Au bumps, Ni—Au bumps and Ni—Au—In bumps having protruding shapes can be used as the higher melting temperature solder balls 17a, 17b, 17c, and 17d.

As for The first level packaging assembly 100, 101, and 103 and the second level packaging assembly 200 shown in FIG. 1 to 13, eutectic alloy can be used as the solder joints 5a, 5b, 5c, and 5d. Since the solder joints 5a, 5b, 5c, and 5d are injected by underfill resin 8, eutectic solders will not be released into the environment.

What is claimed is:

1. A first level packaging assembly comprising:
a chip-mounting base defined by a first surface and a second surface opposite to the first surface;
a plurality of external connection lands disposed on the first surface;
a plurality of solder balls connected to the external connection lands;
a plurality of internal connection lands disposed on the second surface;
a plurality of solder joints connected to the internal connection lands including solder materials having lower melting temperature than the solder balls;
a semiconductor chip defined by a third surface and a fourth surface opposite to the third surface, connected to the solder joints on the third surface; and
an underfill resin sandwiched between the second and third surfaces so as to mold the solder joints.

2. The first level packaging assembly of claim 1, wherein the solder joints are made of lead-free solder alloys, having melting temperatures between 110 ?C. and 200 ?C.

3. The first level packaging assembly of claim 1, wherein the solder joints are alloys including Tin-Zinc.

4. The first level packaging assembly of claim 1, wherein the solder joints are alloys including Tin-Bismuth.

5. The first level packaging assembly of claim 1, wherein the solder joints are alloys including Tin-Indium.

6. The first level packaging assembly of claim 1, wherein the solder joints are alloys including Tin-Bismuth-Silver.

7. The first level packaging assembly of claim 1, wherein the solder joints include a plurality of solder bumps having lower melting temperatures than Tin-Pb alloys, and a plurality of solder balls having higher melting temperatures than the solder bumps.

8. The first level packaging assembly of claim 1, wherein the solder joints comprise a first group including a plurality of solder joints having lower melting temperatures than Tin-Pb alloys, and a second group including a plurality of solder joints having higher melting temperatures than the first group.

9. The first level packaging assembly of claim 8, wherein the first group includes lead-free solder alloy, having a melting temperature of 110-200 degrees C.

10. The first level packaging assembly of claim 1, wherein a low dielectric constant film is applied to a circuit element disposed on the third surface of the semiconductor chip.

11. A second level packaging assembly comprising:
a chip-mounting base defined by a first surface and a second surface opposite to the first surface;
a plurality of external connection lands disposed on the first surface;
a plurality of solder balls connected to the external connection lands;
a plurality of internal connection lands disposed on the second surface;
a plurality of solder joints connected to the internal connection lands including solder materials having lower melting temperatures than the solder balls;
a semiconductor chip defined by a third surface and a fourth surface opposite to the third surface, connected to the solder joints on the third surface;
an underfill resin sandwiched between the second and third surfaces so as to mold the solder joints; and
a board having a plurality of mounting pads, connected with the solder balls.

12. A method of assembling a first level packaging assembly comprising:
connecting a plurality of internal connection lands disposed on a second surface of a chip-mounting base defined by a first surface and the second surface opposite to the first surface with a plurality of chip-side internal connection lands disposed on a third surface of a semiconductor chip defined by the third surface and the fourth surface opposite to the third surface, by a plurality of solder joints between the internal connection lands and the chip-side internal connection lands;
injecting an underfill resin between the second and the third surfaces so as to mold the solder joints; and
disposing a plurality of solder balls having higher melting temperatures than the solder joints on the external connection lands disposed on the first surface.

13. The method of claim 12, wherein the solder joints are made of lead-free solder alloys, having melting temperatures between 110 ?C. and 200 ?C.

14. The method of claim 12, wherein alloys containing Tin-Zinc are used as the solder joints.

15. The method of claim 12, wherein alloys containing Tin-Bismuth are used as the solder joints.

16. The method of claim 12, wherein alloys containing Tin-Bismuth are used as the solder joints.

17. The method of claim 12, wherein the solder joints are formed by a first group having lower melting temperatures than Sn—Pb alloys disposed on the internal connection lands and a second group having higher melting temperatures than the first group disposed on the chip-side internal connection lands.

18. The method of claim 17, wherein alloys containing Tin-Zinc are used as the first group.

19. The method of claim 17, wherein alloys containing Tin-Bismuth are used as the first group.

20. The method of claim 17, wherein a low dielectric constant film is applied to circuit elements formed on the third surface of the semiconductor chip
